(19) United States
(12) Patent Application Publication
(10) Pub. No.: US 2017/0250137 A1
(43) Pub. Date: Aug. 31, 2017

(54) SEMICONDUCTOR DEVICE

(71) Applicant: KABUSHIKI KAISHA TOSHIBA, Tokyo (JP)

(72) Inventors: Koji ARAKI, Himeji Hyogo (JP); Satoshi HATTORI, Ibo Hyogo (JP)

(21) Appl. No.: 15/253,514

(22) Filed: Aug. 31, 2016

(30) Foreign Application Priority Data
Feb. 25, 2016 (JP) 2016034711

(51) Int. Cl. H01L 23/538; H01L 23/00; H01L 23/29; H01L 23/31

(52) U.S. Cl. CPC H01L 23/5381; H01L 23/3121; H01L 24/45; H01L 24/49; H01L 24/06; H01L 23/293; H01L 2224/04042; H01L 2224/05111; H01L 2224/0512; H01L 2224/05139; H01L 2224/05116

(57) ABSTRACT

According to one embodiment, there is provided a semiconductor device including a first wiring, a semiconductor chip, a first bonding member, having a first melting temperature, located between the first wiring and the semiconductor chip, and a second wiring including a first connection unit and a second connection unit spaced from the first connection unit. A second bonding member having a second melting temperature higher than the first melting temperature is located between the semiconductor chip and the first connection unit. A third wiring is also provided, and a third bonding member having a third melting temperature lower than the second melting temperature is located between the second connection unit and the third wiring.

### CROSS-REFERENCE TO RELATED APPLICATION

This application is based upon and claims the benefit of priority from Japanese Patent Application No. 2016-034711, filed Feb. 25, 2016, the entire contents of which are incorporated herein by reference.

### FIELD

Embodiments described herein relate generally to a semiconductor device.

### BACKGROUND

Generally, a known semiconductor device configuration includes a semiconductor chip bonded on a frame bed by a bonding material such as solder or the like. In such a configuration, electrodes on the semiconductor chip are generally connected by wire bonding and sealed by mold resin.

In another known semiconductor device configuration electrodes on the semiconductor chip are connected using a plate shaped conductive metal member instead of wire bonding.

### DESCRIPTION OF THE DRAWINGS

FIG. 1 is a schematic sectional view of a semiconductor device of the embodiment.

FIGS. 2A to 2E are pattern diagrams of the semiconductor device of the embodiment.

FIG. 3 is a schematic sectional view of a semiconductor device of a comparative example.

### DETAILED DESCRIPTION

According to an exemplary embodiment, there is provided a semiconductor device including stable electrical connections therein.

In general, according to one embodiment, there is provided a semiconductor device including a first wiring, a semiconductor chip, a first bonding member, having a first melting temperature, between the first wiring and the semiconductor chip, a second wiring including a first connection unit and a second connection unit spaced from the first connection unit, a second bonding member, having a second melting temperature higher than the first melting temperature, between the semiconductor chip and the first connection unit, a third wiring, and a third bonding member, having a third melting temperature lower than the second melting temperature, between the second connection unit and the third wiring.

Hereinafter, the embodiment of the disclosure is described with reference to the drawings.

Herein, where the same reference numerals are attached to the same elements in different modification examples or embodiments, repeated description thereof will be omitted when appropriate.

Herein, in order to describe a positional relationship of components or the like, the upward direction of the drawing is referred to as “up”, and the downward direction of the drawing is referred to as “down”. Herein, the concept of “up” and “down” does not necessarily indicate a relationship with the direction of gravity.

### First Embodiment

The semiconductor device according to the embodiment includes a first wiring, a semiconductor chip, a first bonding member having a first melting temperature located between the first wiring and the semiconductor chip, a second wiring including a first connection unit and a second connection unit spaced from the first connection unit. A second bonding member having a second melting temperature higher than the first melting temperature is located between the semiconductor chip and the first connection unit. A third wiring is also provided and a third bonding member having a third melting temperature lower than the second melting temperature is located between the second connection unit and the third wiring.

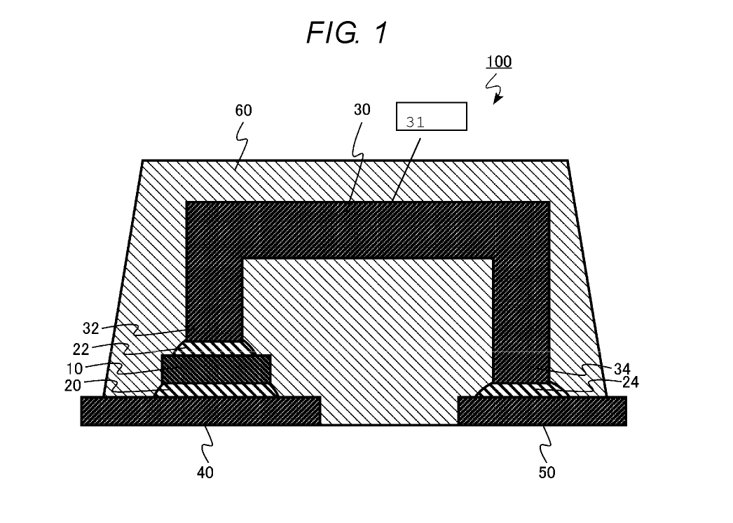

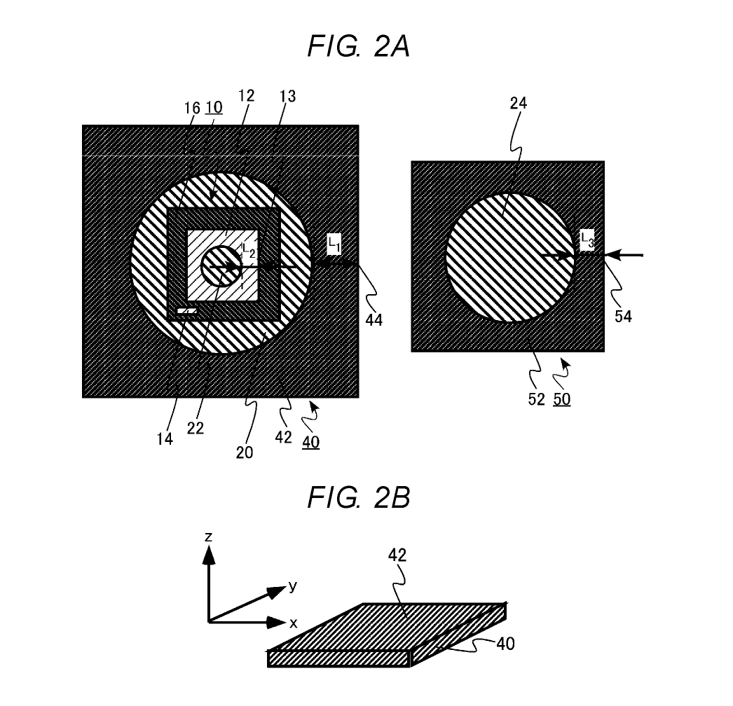

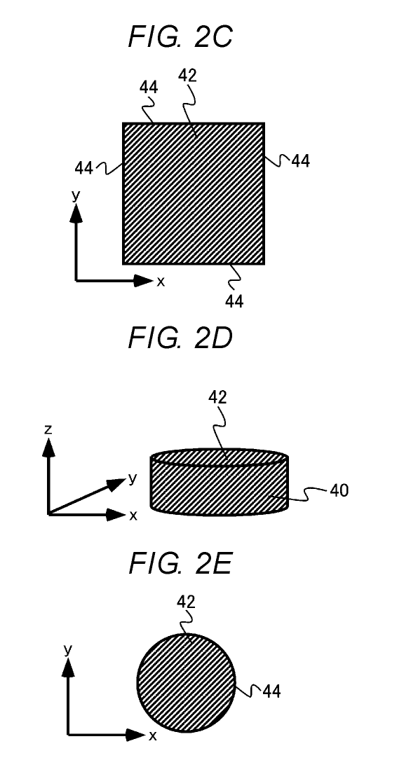

FIG. 1 is a schematic sectional view of a semiconductor device 100 according to the embodiment. FIGS. 2A to 2E are pattern diagrams of the semiconductor device 100 according to the embodiment. FIG. 2A is a pattern diagram of a first surface 42 and a second surface 52 of the semiconductor device 100 according to the embodiment.

The semiconductor device 100 includes a first wiring (frame bed) 40, a third wiring (lead) 50, a semiconductor chip 10, a first bonding member 20, a second bonding member 22, a third bonding member 24, a second wiring (connector) 30, and a mold resin 60 (encapsulant).

The semiconductor chip 10 is, for example, an n-type vertical metal oxide semiconductor field effect transistor (MOSFET). A drain electrode (not illustrated) is provided on the lower side surface of the semiconductor chip 10. In addition, an electrode 12 that is a source electrode and a gate pad 14 that is a gate electrode are provided on the upper side surface of the semiconductor chip. A sealing resin 16 preferably uses, for example, polyimide, as resin for sealing the MOSFET or the electrode. The semiconductor chip 10 can also preferably use, for example, an insulated gate bipolar transistor (IGBT).

For example, the second wiring 30 is a wiring formed by bending a conductive metal member such as strap or strip of copper. The second wiring 30 may be formed by cutting, extrusion, drawing process, casting, forging, crushing processing, electrical discharge machining, or the like. The second wiring 30 includes a first connection unit 32 connected to a bridge portion 31, and a second connection unit 34 extending from the bridge portion 31 on the side of the bridge portion 31 opposite to the location of the first connection unit 32.

For example, the first wiring 40 and the third wiring 50 are plate shaped and contain a metal such as copper (or iron-nickel alloy) or the like. The first wiring 40 has a first surface 42. The third wiring 50 has a second surface 52 as shown in FIG. 2A.

The first bonding member 20, the second bonding member 22, and the third bonding member 24 are, for example, solders. The first bonding member 20 has a first melting temperature. The first bonding member 20 is provided between the first wiring 40 and the semiconductor chip 10. The first bonding member 20 electrically connects the first surface 42 of the first wiring 40 to the drain electrode of the semiconductor chip 10. The second bonding member 22 has a second melting temperature higher than the first melting temperature. The second bonding member 22 is provided between the semiconductor chip 10 and the first connection unit 32. The second bonding member 22 electrically connects the electrode 12 of the semiconductor chip 10 to the first connection unit 32. The third bonding member 24 has a third melting temperature lower than the second melting temperature. The third bonding member 24 is provided between the second connection unit 34 and the third wiring 50. The third bonding member 24 electrically connects the second surface 52 of the second wiring to the second connection unit 34 by.

It is preferable that the first bonding member 20 and the third bonding member 24 are Pb—Sn—Ag based solders containing Pb (lead), Sn (tin), and Ag (silver). In addition, it is preferable that the second bonding member 22 is a Sn—Sb—Ag—Cu based solder containing Sn, Sb (antimony), Ag, and Cu. Alternatively, the first bonding member 20 may be a Sn—Ag based solder containing Sn and Ag.

The mold resin 60 seals the first wiring 40, the third wiring 50, the semiconductor chip 10, the first bonding member 20, the second bonding member 22, the third bonding member 24, and the second wiring 30, such that at least a portion of the first wiring 40 and the second wiring 50 are exposed at a surface of the mold resin. For example, epoxy resins containing a filler of silica (SiO₂) or the like are preferably used as the mold resin 60.

As shown in FIG. 2A a first distance L₁ between the first bonding member 20 and a side 44 of the first surface is longer than a second distance L₂ between the second bonding member 22 and a side of the n electrode 13. In addition, a third distance L₃ between the third bonding member 24 and a side 54 of the second surface is longer than the second distance L2. When a plurality of the electrodes 12 are provided, the electrode 12 the longest distance among the plurality of electrodes 12 is L2. In addition, when the first surface 42 and the second surface 52 include a portion not having electrical conductivity, the first distance L1 and the third distance L3 are determined excluding the portion not having electrical conductivity.

It is further preferable that the first melting temperature is lower than the third melting temperature. In this case, it is preferable that the first distance L1 is longer than the third distance L3.

FIG. 2B, FIG. 2C, FIG. 2D, and FIG. 2E are pattern diagrams showing sides 44 of the first surface of the semiconductor device 100 according to the embodiment. An axis orthogonal to an x-axis is a y-axis, and an axis orthogonal to the x-axis and the y-axis is a z-axis. As illustrated in FIG. 2B, it is assumed that the first wiring 40 is a rectangular parallelepiped having a first surface 42 of a rectangular shape in parallel with an x-y plane. In this case, as illustrated in FIG. 2C, four sides in the periphery of the first surface 42 of a rectangle shape described above are the sides 44 of the first surface. In addition, as illustrated in FIG. 2D, another version of the first wiring 40 is a column having a first surface 42 of a circular shape parallel with the x-y plane. In this case, as illustrated in FIG. 2E, the circular periphery of the first surface 42 is the side 44 of the first surface. The electrode sides 13 and the sides 54 of the second surface have the same structures as described with respect to the sides 44 of the first surface.

Next, a manufacturing method of the semiconductor device 100 according to the embodiment is described. First, the first bonding member 20 is coated on the first wiring 40, for example, by dispensing or the like. Next, the semiconductor chip 10 is arranged on the first bonding member 20. Next, the second bonding member 22 is coated on the semiconductor chip 10, for example, by dispensing or the like. Next, the third bonding member 24 is coated on the third wiring 50, for example, by dispensing or the like. Next, the second wiring 30 is arranged on the second bonding member 22 and the third bonding member 24. Next, the first bonding member 20, the second bonding member 22, and the third bonding member 24 are melted and then cooled and re-solidified in, for example, a reflow furnace. Next, the first wiring 40, the third wiring 50, the semiconductor chip 10, the first bonding member 20, the second bonding member 22, the third bonding member 24, and the second wiring 30 are sealed in the mold resin 60. A manufacturing method of the semiconductor device 100 according to the embodiment is not limited to the above-described method.

Next, operations and effects of the embodiment will be described.

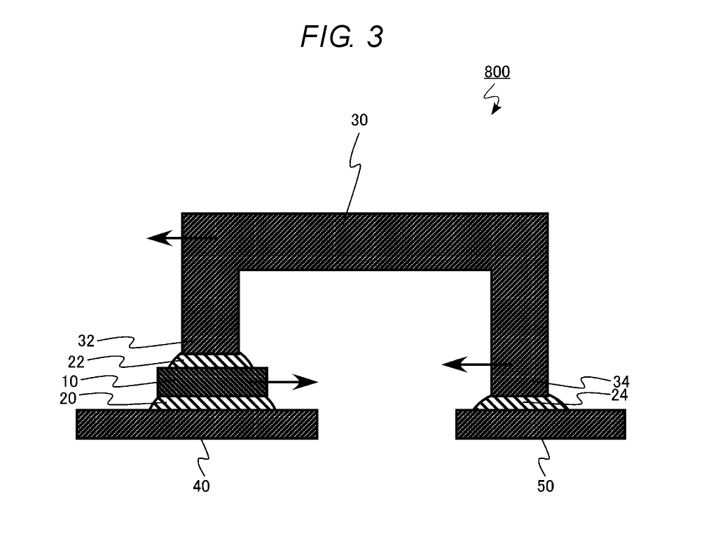

FIG. 3 is a schematic sectional view of a semiconductor device 800 of a comparative example to the device of the embodiment. Here, in the semiconductor device 800, the first bonding member 20, the second bonding member 22, and the third bonding member 24 have the same melting temperature. Generally, there is a non-uniformity of temperature of approximately ±10° within the reflow furnace. Therefore, after complete melting of the members 20, 22 and 24, at the time of re-solidifying the first bonding member 20, the second bonding member 22, and the third bonding member 24, there is a case where the first bonding member 20 or the third bonding member 24 is re-solidified earlier than is the second bonding member 22. In this case, as an arrow illustrated in FIG. 3, since the first connection unit 32 can move on the chip and contact a portion of the semiconductor chip 10 not including the electrode 12 as a result of the movement of the semiconductor chip 10 and the second wiring 30, it tends that electrical connection failure occurs.

In the semiconductor device 100 according to the embodiment, the second melting temperature is higher than the first melting temperature. In addition, the third melting temperature is lower than the second melting temperature. During soldering, there is an effect that components are arranged in the vicinity of the center of the solder surface of the liquid state because of surface tension of the liquid solder, which is known as the self-alignment effect. After complete melting of the first bonding member 20, the second bonding member 22, and the third bonding member 24, the semiconductor chip 10 is arranged in the vicinity of the center of a surface of the first bonding member 20, the first connection unit 32 is arranged in the vicinity of the center of the surface of the second bonding member 22, and the second connection unit 34 is arranged in the vicinity of the center of the surface of the third bonding member 24. When cooling is performed within the reflow furnace the second bonding member 22 having a high melting temperature is first solidified while maintaining a good positional relationship between the semiconductor chip 10 and the second connection unit 34. As a result, the semiconductor chip 10, the second bonding member 22, and the second wiring 30 have a structure in which their relative positional relationship is fixed.

Thereafter, while the above-described structure including the semiconductor chip 10, the second bonding member 22, and the second wiring 30 are held together by the solidified second member 22, the semiconductor chip 10 is located in the vicinity of the center of the surface of the still melted first bonding member 20 by the self-aligning characteristics of the solder, and the second connection unit 34 is located in the vicinity of the center of the surface of the melted third bonding member 24 by the self-aligning characteristics of the solder. Then, the first bonding member 20 and the third bonding member 24 are re-solidified. When the solidification occurs according to the described sequence, since the above-described structure does not move because it is fixed by the second bonding member 22, bonding is performed while the positional relationship is maintained with respect to the semiconductor chip 10, the first wiring 40, the second connection unit 34, and the third wiring 50. Accordingly, it is possible to form a semiconductor device 100 having a stable and positionally accurate electrical connection.

Where the first distance L1 is longer than the second distance L2, the third distance L3 is longer than the second distance L2, and there is a margin in a positional deviation amount from a predetermined position, the semiconductor chip 10 and the second wiring 30 can be fixed on the first wiring 40 and the third wiring 50. With this, it is possible to provide the semiconductor device 100 having a more stable and positionally accurate electrical connection.

If the first melting temperature is lower than the third melting temperature, in the process of lowering of the temperature within the reflow furnace, by first re-solidifying the second bonding member 22 and then re-solidifying the third bonding member 24, the third wiring 50, the third bonding member 24, the second wiring 30, the second bonding member 22, and the semiconductor chip 10 are positionally fixed such that an integrated member is created. Thereafter, the first bonding member 20 is re-solidified. In this case, since the semiconductor chip 10 is fixed to the second wiring 30 by the second bonding member 22, unintentional positional deviation does not occur between the first unit 32 and the semiconductor chip 10. Accordingly, the electrical connection failure does not occur as a result of contacting a portion of the semiconductor chip 10 and the first wiring 40 that does not include the electrode 12. In this case, since the first distance L1 is longer than the third distance L3 and a permissible positional deviation amount of the first wiring 40 is greater than a permissible positional deviation amount on the third wiring 50, it is possible to further stably fix the semiconductor chip on the first wiring 40.

It is preferable that the first bonding member 20 and the third bonding member 24 are Pb—Sn—Ag based solders containing Pb (lead), Sn (tin), and Ag (silver). In addition, it is preferable that the second bonding member 22 is Sn—Sb—Ag—Cu based solder containing Sn, Sb (antimony), Ag, and Cu. Since the melting temperature of the Pb—Sb—Ag based solder is 307° C. and the melting temperature of the Sn—Sb—Ag—Cu based solder is 350° C., the second melting temperature is higher than the first melting temperature, and the third melting temperature is lower than the second melting temperature.

Alternately, the first bonding member 20 may be Sn—Ag based solder containing Sn and Ag. Since the melting temperature of the Sn—Ag based solder is 230° C., here the second melting temperature is higher than the first melting temperature, the third melting temperature is lower than the second melting temperature, and the first melting temperature is lower than the third melting temperature.

As described above, according to the semiconductor device according to the embodiment, it is possible to provide the semiconductor device including stable and positionally accurate electrical connection.

### Second Embodiment

The semiconductor device according to the embodiment is different from the semiconductor device according to the first embodiment in that the first melting temperature is higher than the third melting temperature. Here, the description of elements described with respect to the first embodiment temperature is omitted.

When the first melting temperature is higher than the third melting temperature, after the first bonding member 20 and the second bonding member 22 are re-solidified, the second connection unit 34 remains located on the surface of the melted third bonding member 24. In this case, it is possible to stably fix the second connection unit 34 on the third wiring 50, by the third bonding member 24. In this case, it is preferable that the Pb—Sn—Ag based solder is used as the first bonding member 20, the Sn—Sb—Ag—Cu based solder is used as the second bonding member 22, and the Sn—Ag based solder is used as the third bonding member 24. In addition, by setting the third distance L3 to be longer than the first distance L1, it is possible to more stably and positionally accurately fix the second connection unit 34 on the third wiring 50.

As described above, it is possible to provide a semiconductor device including stable and positionally accurate electrical connections.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor device, comprising:
a first wiring;
a semiconductor chip;
a first bonding member, having a first melting temperature, between the first wiring and the semiconductor chip;
a second wiring including a first connection unit and a second connection unit spaced from the first connection unit;
a second bonding member, having a second melting temperature higher than the first melting temperature, between the semiconductor chip and the first connection unit;
a third wiring; and
a third bonding member, having a third melting temperature lower than the second melting temperature, between the second connection unit and the third wiring.

2. The semiconductor device according to claim 1, wherein
at least one of the first bonding member or the third bonding member includes lead, tin, and silver, and
the second bonding member includes tin, antimony, and silver.

3. The semiconductor device according to claim 1, wherein
the first wiring has a first surface electrically connected to the semiconductor chip by the first bonding member,
the third wiring has a second surface electrically connected to the second connection unit by the third bonding member,
the semiconductor chip includes an electrode electrically connected to the first connection unit by the second bonding member,
a first distance between the first bonding member and a side of the first surface is longer than a second distance between the second bonding member and a side of the electrode, and
a third distance between the third bonding member and a side of the second surface is longer than the second distance.

4. The semiconductor device according to claim 3, wherein the first distance is longer than the third distance.

5. The semiconductor device according to claim 1, wherein the first melting temperature is lower than the third melting temperature.

6. The semiconductor device according to claim 1, wherein the first melting temperature and the third melting temperature are the same temperature.

7. The semiconductor device according to claim 1, wherein
the second wiring further comprises a conductive bridge connected to the first connection unit and to the second connection unit, and
the second connection unit is on the opposite side of the conductive bridge from the location of the first connection unit with respect to the conductive bridge.

8. The semiconductor device according to claim 1, further comprising a resin encapsulant surrounding the first connection unit, the second connection unit, the first, second and third connection members, and the semiconductor chip.

9. A semiconductor device, comprising:
a first wiring;
a semiconductor chip;
a first bonding member, having a first melting temperature, between the first wiring and the semiconductor chip;
a second wiring including a first connection unit and a second connection unit spaced from the first connection unit;
a second bonding member, having a second melting temperature different from the first melting temperature, between the semiconductor chip and the first connection unit;
a third wiring; and
a third bonding member, having a third melting temperature different from the second melting temperature, between the second connection unit and the third wiring.

10. The semiconductor device according to claim 9, wherein the first and third melting temperatures are the same, and they are lower than the second melting temperature.

11. The semiconductor device according to claim 9, wherein
at least one of the first bonding member or the third bonding member includes lead, tin, and silver, and
the second bonding member includes tin, antimony, and silver.

12. The semiconductor device according to claim 9, wherein
the first wiring has a first surface electrically connected to the semiconductor chip by the first bonding member,
the third wiring has a second surface electrically connected to the second connection unit by the third bonding member,
the semiconductor chip includes an electrode electrically connected to the first connection unit by the second bonding member,
a first distance between the first bonding member and a side of the first surface is longer than a second distance between the second bonding member and a side of the electrode, and
a third distance between the third bonding member and a side of the second surface is longer than the second distance.

13. The semiconductor device according to claim 12, wherein the first distance is longer than the third distance.

14. The semiconductor device according to claim 9, wherein the first melting temperature is lower than the third melting temperature.

15. The semiconductor device according to claim 9, wherein
the second wiring further comprises a conductive bridge connected to the first connection unit and to the second connection unit, and
the second connection unit is located on the opposite side of the conductive bridge from the location of the first connection unit with respect to the conductive bridge.

16. A semiconductor device package, comprising:
a first wiring;
a semiconductor chip;
a first bonding member, having a first melting temperature, between the first wiring and the semiconductor chip;
a second wiring including a first connection unit, and a second connection unit spaced from the first connection unit;
a second bonding member, having a second melting temperature different from the first melting temperature, between the semiconductor chip and the first connection unit;
a third wiring;
a third bonding member, having a third melting temperature different than the second melting temperature, between the second connection unit and the third wiring; and
a resin encapsulant surrounding the first connection unit, the second connection unit, the first, second and third connection members and the semiconductor chip, wherein
the second melting temperature is higher than at least one of the first and the third melting temperatures.

17. The semiconductor device package according to claim 16, wherein portions of the first wiring and the third wiring are exposed at a surface of the resin encapsulant.

18. The semiconductor device package according to claim 16, wherein the resin encapsulant is a mold resin.

19. The semiconductor device package according to claim 16, wherein
the first wiring has a first surface electrically connected to the semiconductor chip by the first bonding member,
the third wiring has a second surface electrically connected to the second connection unit by the third bonding member,
the semiconductor chip includes an electrode electrically connected to the first connection unit by the second bonding member,
a first distance between the first bonding member and a side of the first surface is longer than a second distance between the second bonding member and a side of the electrode, and
a third distance between the third bonding member and a side of the second surface is longer than the second distance.

20. The semiconductor device package according to claim 16, wherein:
the second wiring further comprises a conductive bridge connected to the first connection unit and to the second connection unit, and
the second connection unit is located on the opposite side of the conductive bridge from the location of the first connection unit with respect to the conductive bridge.
